(19) United States
(12) Patent Application Publication
(10) Pub. No.: US 2024/0176943 A1
(43) Pub. Date: May 30, 2024

(54) AUTO-CREATION OF CUSTOM STANDARD CELLS

(71) Applicant: X DEVELOPMENT LLC, Mountain View, CA (US)

(72) Inventors: Xiaoqing Xu, Mountain View, CA (US); Herman Schmit, Marina, CA (US); Alessandro Tempia Calvino, Mountain View, CA (US)

(73) Assignee: X DEVELOPMENT LLC, Mountain View, CA (US)

(21) Appl. No.: 18/235,437

(22) Filed: Aug. 18, 2023

Related U.S. Application Data
(60) Provisional application No. 63/426,919, filed on Nov. 21, 2022.

(51) Int. Cl. G06F 30/398; G06F 30/31

(52) U.S. Cl. CPC G06F 30/398; G06F 30/31

(57) ABSTRACT

The technology involves the auto-creation of custom standard cells. The process may include receiving specifications for implementing a set of functionalities in an integrated circuit to be fabricated. From this, the system identifies which cells are required to implement the set of functionalities. The identified cells are evaluated against a standard cell library stored in memory to determine which of the cells are not in the standard cell library. The system automatically creates the cells that are not in the standard cell library. The system can then utilize the automatically created cells to fabricate the integrated circuit. Benefits of such an approach include reduced design, development time and improved design quality of results. The resulting new cells may have fewer transistors, less area/power and improved performance than a standard cell from a preexisting library, especially since such standard cells would not necessarily be configurable to perform the desired functions.

### CROSS-REFERENCE TO RELATED APPLICATIONS

This application claims the benefit of the filing date and priority to U.S. Provisional Patent Application No. 63/426,919, filed Nov. 21, 2022, the entire disclosure of which is incorporated herein by reference.

### BACKGROUND

Integrated circuit (IC) development, involving design and fabrication, can be complicated and time consuming. The process can be particularly challenging with specialized integrated circuits, such as application-specific integrated circuits (ASICs) or system-on-chip (SoC) devices having many on-chip components such as transistors. There are a variety of approaches that have been employed to design such devices. In some approaches, a standard cell library may be used when designing the IC. The library contains a set of cell structures that may comprise transistors and interconnections between them, in which the cell structures perform specific functions such as a Boolean logic function or a state or storage function. Each cell is pre-characterized, and can be placed and routed at the transistor level. If a function to synthesize is not directly implementable in one cell, a combination of cells may be used to achieve it.

As part of the design process, technology mapping is used to express the Boolean logic functions associated with a netlist as an arrangement of elements selected from the standard cell library. This can be done to achieve an objective such as minimizing the total area or minimizing signal delay. However, the overall process may be challenging when it is not clear which cells should be used to design a circuit. In addition, existing approaches can be inefficient when going from logic gate abstraction to standard cell mapping, both in terms of the number of transistors required as well as the physical size of the circuit (e.g., according to poly pitch or other physical size factor).

### SUMMARY

Aspects of the technology involve the auto-creation of custom standard cells. In conventional approaches, it may be assumed that there is a standard cell library, which may be provided by a vendor or a foundry. However, such a library may not cover certain functionality to be implemented in a given integrated circuit. Thus, according to one aspect of the technology, the system evaluates an input design and identifies which cells would be required to implement that design. The system may evaluate the standard cell library against the identified cells, determining which cells are not in that library. The system can then create those cells, either adding them to the standard cell library or maintaining them in a separate library. The system may make recommendations to an engineer or other user regarding what kinds of cells to make. This could include identifying, in a graphical user interface (GUI), what the new cell(s) would look like, indicating the number of transistors, overall size, power requirements and/or other factors, etc. Then, upon user selection the system may proceed to generate the new cells for use in a given device.

The technical benefits include reduced design, development time and improved design quality of results, because the auto-creation of specialized cell does not require the developer to manually design a cell to perform specified functions. The resulting new cells may have fewer transistors, less area/power and improved performance than a standard cell from a preexisting library, especially since such standard cells would not necessarily be configurable to perform the desired functions.

According to one aspect of the technology, a computer-implemented method comprises: receiving, by one or more processors of a computer system, specifications for implementing a set of functionalities in an integrated circuit to be fabricated; identifying, by the one or more processors, which cells are required to implement the set of functionalities; evaluating, by the one or more processors, the identified cells against a standard cell library stored in memory to determine which of the cells are not in the standard cell library; automatically creating, by the one or more processors, the cells that are not in the standard cell library; and utilizing the automatically created cells to fabricate the integrated circuit.

The method may further comprise storing the automatically created cells in the memory. In this case, storing the automatically created cells in the memory may include adding the automatically created cells to the standard cell library. Alternatively or additionally, the method of may further comprise generating, by the one or more processors for presentation via a graphical user interface, a recommendation to a user regarding employing the automatically created cells to fabricate the integrated circuit. Here, the recommendation may include information of at least one of a number of transistors utilized, overall cell size, or a power requirement.

Alternatively or additionally to the above, evaluating the identified cells against the standard cell library may include employing a lookup table (LUT) mapper. Here, the method may further comprise the LUT mapper using factored form literals to estimate a number of transistors of a function to be utilized by the integrated circuit. The LUT may be is cut-based. In this case, the method may further comprise the LUT mapper using a series of heuristics to cover a network using cuts while minimizing total area. Alternatively or additionally, the method may further comprise performing global remapping based on the factored form literals over an And-inverter graph (AIG).

According to another aspect of the technology a computing system is provided that comprises memory configured to store a standard cell library, and one or more processors operatively coupled to the memory. The one or more processors are configured to: receive specifications for implementing a set of functionalities in an integrated circuit to be fabricated; identify which cells are required to implement the set of functionalities; evaluate the identified cells against the standard cell library stored in the memory to determine which of the cells are not in the standard cell library; automatically create the cells that are not in the standard cell library; and cause fabrication of the integrated circuit utilizing the automatically created cells.

In one example, the one or more processors are further configured to store the automatically created cells in the memory. Here, storing the automatically created cells in the memory may include causing the automatically created cells to be added to the standard cell library. Alternatively or additionally, in another example, the one or more processors are further configured to generate, for presentation via a graphical user interface, a recommendation to a user regarding employing the automatically created cells to fabricate the integrated circuit. Here, the recommendation may include information of at least one of a number of transistors utilized, overall cell size, or a power requirement.

Alternatively or additionally, evaluation of the identified cells against the standard cell library may include employing a lookup table (LUT) mapper. Here, the one or more processors may be further configured to apply the LUT mapper using factored form literals to estimate a number of transistors of a function to be utilized by the integrated circuit. The LUT mapper may use a series of heuristics to cover a network using cuts while minimizing total area. Alternatively or additionally, the one or more processors may be further configured to perform global remapping based on the factored form literals over an And-inverter graph (AIG).

Alternatively or additionally, evaluation, the one or more processors may be configured to cause fabrication of the integrated circuit utilizing the automatically created cells by transmitting a file containing the automatically created cells to a fabrication facility.

### BRIEF DESCRIPTION OF THE DRAWINGS

FIG. 1 illustrates an integrated circuit design flow in accordance with aspects of the technology.

FIG. 2 is an example system that may be employed with aspects of the technology.

FIGS. 3A-B illustrate an example factored form and its translation into an AIG in accordance with aspects of the technology.

FIGS. 3A-B illustrate an example factored form and its translation into an AIG in accordance with aspects of the technology.

FIGS. 4A-B illustrate an example optimization of an AIG for factored form literals in accordance with aspects of the technology

FIG. 5 illustrates a table of experimental results for factored form literals optimization in accordance with aspects of the technology.

FIG. 6 illustrates an example CMOS network for a given function and the respective pullup (PU) and pulldown (PD) networks in accordance with aspects of the technology.

FIGS. 7A-B illustrate an example circuit netlist/schematic and corresponding ANDOR graph in accordance with aspects of the technology.

FIGS. 8A-C illustrate exemplary topologies for transistor netlists in accordance with aspects of the technology.

FIG. 9 illustrates an example method in accordance with aspects of the technology.

### DETAILED DESCRIPTION

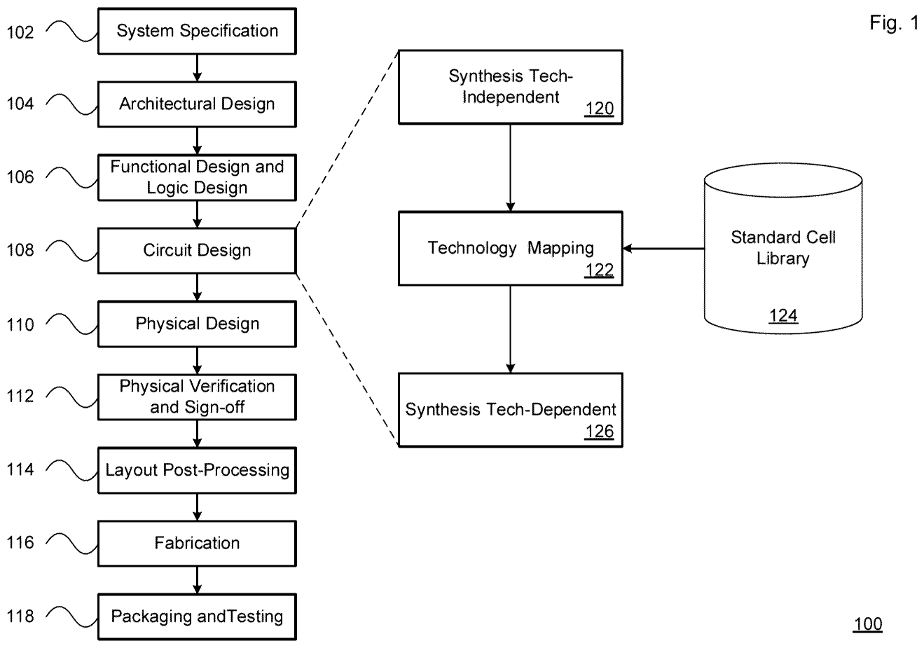

FIG. 1 illustrates an exemplary integrated circuit design flow 100. As shown, the design flow may include preparing a system specification at block 102, such as to identify system-level requirements for the integrated circuit. The system specification is intended to capture the overall goal of the desired integrated circuit. This may include determining the device's cost, performance, general architecture, how off-chip communication will be conducted, etc. The process flow may also include performing architectural design at block 104. At this stage, the design's architecture and its layout are determined by design engineers. This can include integration of memory management, analog and/or mixed-signal components, on-device and external communication, any power constraints, choice of process technology and/or layer stacks, etc.

The process flow continues with performing functional design and logic design at block 106, and performing circuit design at block 108. Functional design may include refinement of the design's specification to achieve the functional behavior of the desired system. Logic design involves adding the design's structure to a behavioral representation of the desired design. Here, considerations include logic minimization, performance enhancement, as well as testability. This stage may consider problems associated with test vector generation, error detection and correction, and the like. By way of example, the functional design and logic design may include generating a behavioral model description (e.g., using HDL) and floor-planning. During circuit design, logic blocks are replaced by corresponding electronic circuits, which may include devices such as transistors. At this stage, circuit simulation may be performed in order to verify timing behavior and other constraints of the system. A Spice tool or other program may be used for circuit simulation.

Once the circuit design is complete, physical design may be performed at block 110 (e.g., component and wiring placement and routing), followed by physical verification and sign-off at block 112 (e.g., to obtain GDSII information with shapes to form the masks used to create the layers for fabricating the integrated circuit). During physical design, the actual layout of the integrated circuit is performed. Here, all of the components are placed and interconnected using metal interconnections. A circuit design that is able to pass testing of a circuit simulator in the circuit design stage may be found to be faulty after it has been packaged, e.g., due to geometric design rule issues. Thus, physical design rules are followed to ensure correctness during chip fabrication. Errors may include short or open circuits, open channels, or other issues may result when physical design rules are not followed. During physical verification and sign-off, the system performs any verification steps that are required before chip manufacturing. This can include design rule checking and correction, timing simulation, electromagnetic simulation, etc.

Layout post-processing occurs at block 114, then fabrication at block 116, and the packaging and testing at block 118. At block 114, the layout post-processing may include geometry processing before actual manufacturing, e.g., any dummy fill insertion, correction for optical proximity, mask optimization, etc. Fabrication comprises semiconductor manufacturing, which includes stages such as lithography patterning (masking), baking or annealing, etching, etc. Then the raw die of the chip is inserted into a package and I/O pins are connected to the package at block 118. Testing of the chip also occurs at this stage.

As shown, in the circuit design phase of block 108, the process may involve technology-independent synthesis at block 120. This step involves transferring the circuit definitions, such as register-transfer-level (RTL) descriptions, into generic data structures such as And-inverter graph (AIG), and optimizing the circuit in terms of nodes and levels. At block 122, technology mapping is performed based on information from a standard cell library 124. This step involves mapping the generic optimized AIG descriptions into real, manufacturable standard cells included in the standard cell library. From this, technology-dependent synthesis is then performed at block 126. This step further optimizes the circuit defined in the gate-level netlist in terms of power, performance and area, using standard-cell-based definitions from block 122.

### Example Integrated Circuit Development System

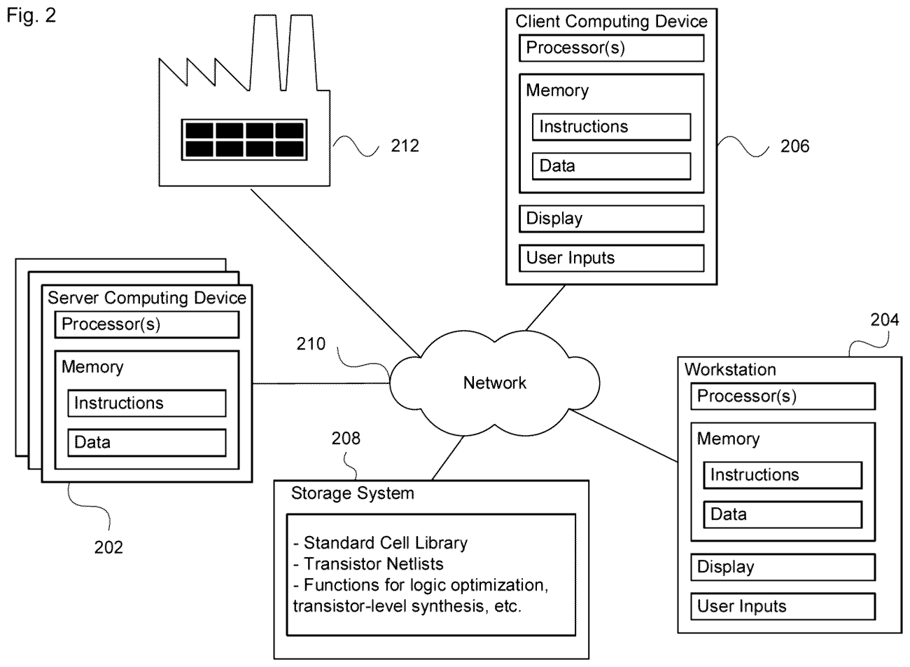

One example of a system for performing circuit design is shown in FIG. 2. In particular, FIG. 2 is a functional diagram, of an example system 200 that includes a plurality of computing devices 202, 204, 206 and a storage system 208 connected via a network 210. System 200 may also include a fabrication facility 212 that is configured to produce integrated circuits designed according to the processes described herein. As shown in FIG. 2, each of computing devices 202, 204 and 206 may include one or more processors, memory, data and instructions.

By way of example, the one or more processors may be any conventional processors, such as commercially available central processing units (CPUs), graphical processing units (GPUs) or tensor processing unites (TPUs). Alternatively, the one or more processors may include a dedicated device such as an ASIC or other hardware-based processor. As shown in FIG. 2, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance.

The data may be retrieved, stored or modified by processor in accordance with the instructions. For instance, although the claimed subject matter is not limited by any particular data structure, the data may be stored in computing device registers, in a relational database as a table having a plurality of different fields and records, XML documents or flat files, HDL information, GDSII information, etc. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 200 and/or the fabrication facility 212.

The various computing devices may communicate directly or indirectly via one or more networks, such as network 210. The network 210 and any intervening nodes may include various configurations and protocols including short range communication protocols such as Bluetooth™ Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 202 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 202 may include one or more server computing devices that are capable of communicating with computing devices 204, 206 and the fabrication facility 212 via the network 210, for instant to transmit one or more files or other records containing automatically created cells to the facility so that the circuitry can be fabricated. In some examples, client computing device 204 may be an engineering workstation used by a developer to perform circuit design and/or other processes for integrated circuit design and fabrication. Client computing device 206 may also be used by a developer, for instance to prepare system requirements for the integrated circuit or manage the manufacturing process with the fabrication facility 212.

Storage system 208 can be of any type of computerized storage capable of storing information accessible by the server computing devices 202, 204 and/or 206, such as a hard-drive, memory card, ROM, RAM, DVD, CD-ROM, flash drive and/or tape drive. In addition, storage system 208 may include a distributed storage system where data is stored on a plurality of different storage devices which may be physically located at the same or different geographic locations. Storage system 208 may be connected to the computing devices via the network 210 as shown in FIG. 2, and/or may be directly connected to or incorporated into any of the computing devices.

Storage system 208 may store various types of information. For instance, the storage system 208 may store a standard cell library, transistor-level netlists. It may also maintain functions for logic optimization and transistor-level synthesis, as well as for performing technology mapping and other processes described herein.

### Improving Standard-Cell Design Flow Using Factored Form Optimization

Factored form is a powerful multi-level representation of a Boolean function that readily translates into an implementation of the function in CMOS technology. In particular, the number of literals of a factored form correlates well with the number of transistors in the CMOS implementation. Aspects of the technology involve developing novel methods for minimizing the total number of factored form literals needed to represent combinational logic given as an and-inverter graph (AIG). The methods lead to reduced literal counts, compared to the traditional methods focusing on minimizing the number of AIG nodes. Experiments show that applying these methods helps reduce area after technology mapping by an additional 2.6% on average. Deploying these methods as part of an industrial standard-cell design flow may be able to dramatically reduce design costs and power consumption. Additionally, this work enables efficient transistor-level synthesis with application in design automation.

As explained in Appendix 1, logic representations are the key to represent the functionality in EDA tools. They are fundamental for efficiently storing data in memory and running optimization algorithms on the logic. Sum-of-products (SOP) is a basic representation of Boolean logic. A powerful extension of SOPs to a multi-level representation is the factored form. An example is shown below:
Sum-of-products: ab+ac+ad+cbd
Factored Form: a(b+c+d)+cbd

A multi-level circuit may be represented as a directed acyclic graph (DAG) where each node is a gate, or a primary input, or a primary output. Multi-level circuits represent the majority of the circuits in ASICs and FPGAs and tend to be smaller, more power efficient, and faster compared to the two-level counterpart. Functionality in DAGs is usually expressed using few primitives such that DAGs are easy to manipulate and have small memory footprint. The most common multi-level representation is the AIG, where nodes act as two-input ANDs.

Logic optimization is a key element that enables designing efficient circuits. The most common and powerful optimization algorithms perform resubstitution, rewriting, refactoring, and balancing. Optimization scripts may comprise a combination of those algorithms.

One application of AIGs in synthesis is the representation of DAGs coming from Boolean decomposition and factored forms. In particular, factored forms can be represented as syntax trees where nodes are AND or OR operations, and leaves are literals (variables complemented or not complemented). Thus, factored forms can be directly represented by an AIG by translating ANDs to ANDs, and ORs to ANDs using De Morgan's law.

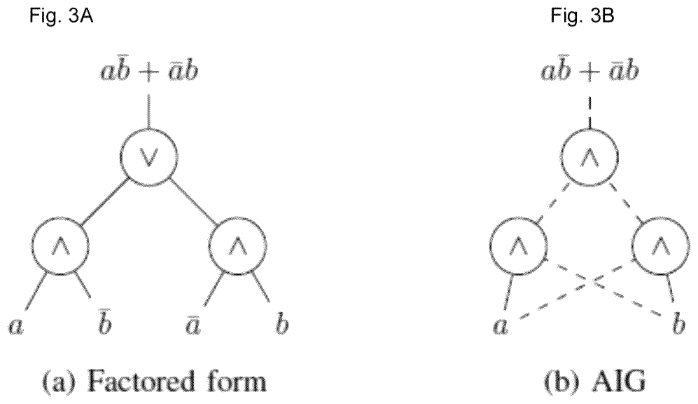

As an example, FIGS. 3A-B show a representation of a XOR2 in factored form (FIG. 3A) and its translation into an AIG (FIG. 3B). In a factored form graph, the number of literals is given by its number of leaves. For instance, in FIG. 3A the number of literals is 4. In the AIG representation of factored forms, the number of literals is computed as the sum of the fanout size of the primary inputs of the graph.

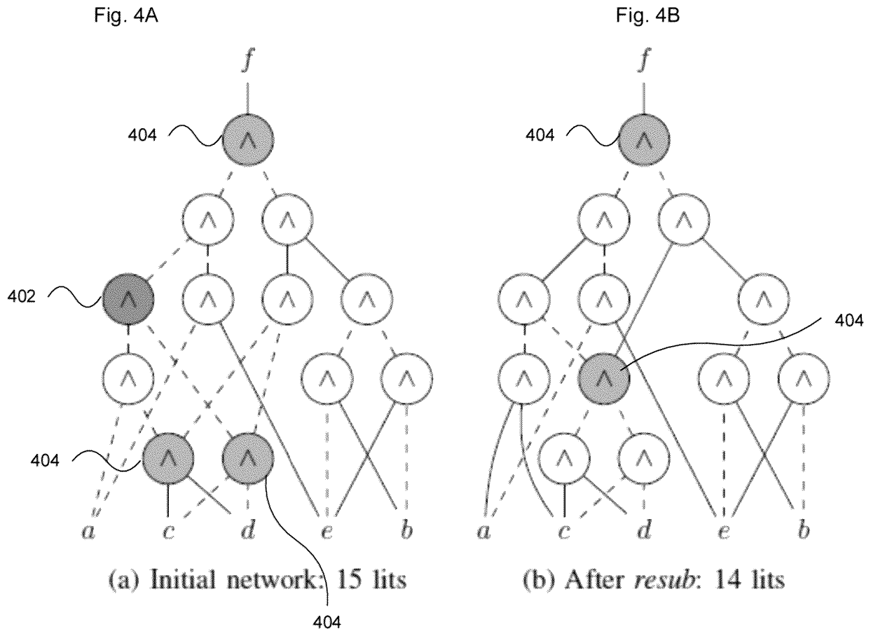

FIGS. 4A-B illustrate optimization of an AIG for factored form literals. FIG. 4A shows the initial network. FIG. 4B shows the result with reduced literal count after resubstitution is applied to the shaded gate 402. Other shaded gates (404) are roots of factored forms. The AIG can be covered using 3 factored forms rooted at the green nodes 404. The one rooted at f is connected to a, e, b and the other two nodes 404 in green. The other two rooted at the green nodes 404 at the bottom are connected to c and d. The total number of factored form literals is 15 (“15 lits”) and it is given by the fanout size of the primary inputs and of the two green nodes 404 with multiple fanout. From the definition, it follows that factored form literals in an AIG can be used as an additional cost function to carry the optimization of combinational logic. The simple definition of literal count makes it also very efficient to compute.

Factored form optimization methods for literals reduction and results after technology mapping have been explored, as discussed in Appendix 1. The following Boolean resynthesis script was created, called compress2ff, which comprises the following commands:
rs -f -K 12 -N 2-1;
rfz -f -1; rfz -f -1;
rs -f -K 10 -N 3-1;
rw -f -1;
b;
rs -f -K 8 -N 2-1;
rwz -1;
rs -f -K 12 -N 2-1;
rfz -f -1;
rs -f -K 12 -N 2-1;
rfz -f -1;
rwz -1;
rf -f -1;
rs -f -K 12 -N 2-1,
   in which rs is resubstitution, rw is rewriting, rf is refactoring, and b is balancing. Commands ending with z stand for allowing zero-gain transformations. The switch -f activates the factored form optimization over the size one. The flag -1 allows transformations to increase the level of the logic. Options -K and -N define the limit of the cut inputs and the limit number of added nodes respectively.

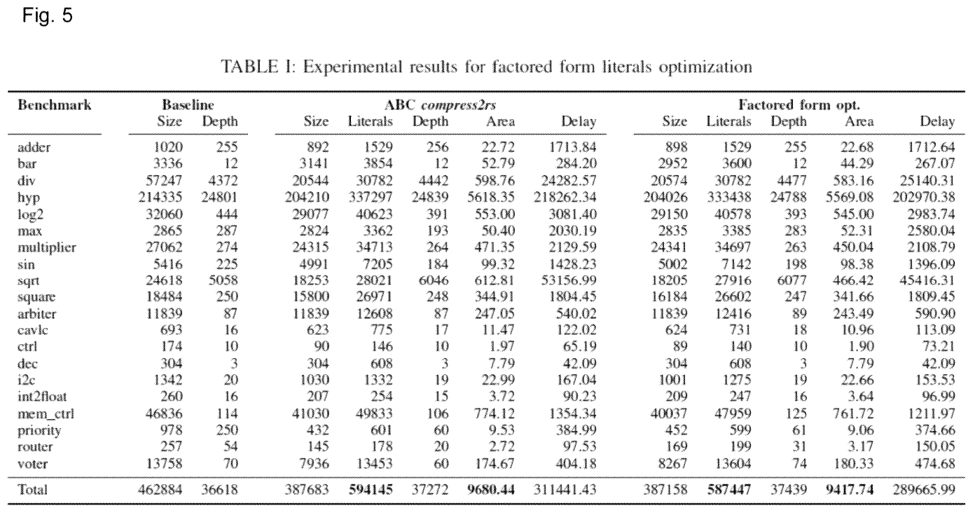

For technology independent synthesis, this approach was compared to compress2rs which is a well-known default script in ABC for size optimization. For technology mapping, the best area-oriented mapper in ABC was used, called amap. Since the mapper supports AIGs with maximum 4000 logic levels, the approach employs the mapper of for area using the command &nf -R 1000 for designs with higher depths. As a technology library, it was mapped to a 3 nm node technology. Table I in FIG. 5 shows the results of the experiments.

### Transistor-Level Synthesis

The literal count in factored forms is a known proxy for transistor count in CMOS transistor networks. Transistor count is a fundamental measure that strongly correlates with area. Even if transistor count alone does not capture other important factors affecting area and power such as transistor ordering, placement, and routing, it is one of the best indicators. In particular, factored forms describe the serial-parallel connection of transistors. A serial connection is described by an AND operator, while a connection in parallel is described by an OR operator. This relation allows a developer to generate a CMOS transistor networks from factored forms. Since the pulldown and pullup networks in CMOS are complementary, two factored forms are needed, one the dual of the other.

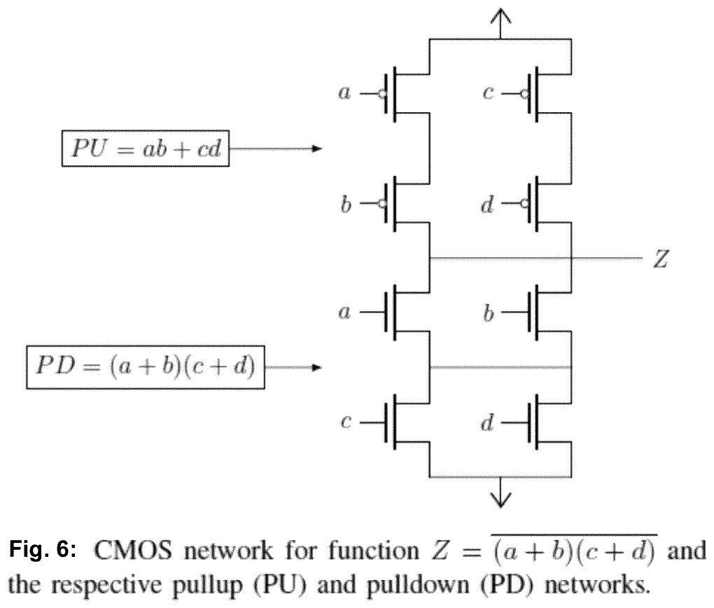

FIG. 6 depicts a mapping of a function in factored form into a transistor network. In particular, FIG. 6 illustrates a CMOS network for a given function Z=(̅a̅+̅b̅)̅ (̅c̅+̅d̅)̅ and the respective pullup (PU) and pulldown (PD) networks.

Since an AIG could contain many factored forms, it naturally describes the connection of transistors in a multi-stage network. Using this relation, one can extract a transistor-level network after mapping each factored form into CMOS using technology mapping, the natural translation of factored forms, or other method. This property opens up to transistor-level synthesis offering flexibility in functionality, not restricted by standard cell libraries, and compact layout thanks to transistor placement opportunities. Hence, factored form literal optimization plays an important role in reshaping combinational circuits modeled as AIGs to minimize globally the number of transistors.

Generating Single-Stage Transistor Networks from Boolean Functions

According to one aspect of the technology, given a Boolean function, the goal is to find a transistor level netlist that implements the function. The method supports CMOS using only parallel-series connections of transistors. Serial connections can be interpreted as ANDs while parallel connections can be interpreted as ORs.

One stage transistor-level networks are composed of two main blocks called pulldown and pullup networks. The former one is connected between VDD and the output, is composed of PMOS transistors, and is responsible for bringing a high (‘1’) state to the output. Conversely, the latter is connected between the output and VDD, is composed of NMOS transistors, and is responsible for bringing a low (‘0’) state to the output. The function of the pulldown and pullup network are designed such that when one network behaves as a short circuit, the other behaves as an open circuit. This relation is called duality, i.e., one function can be derived from the other by negating inputs and outputs.

This method starts by representing the function as a sum-of-products (SOP). A SOP contains a disjunction (OR) of terms (AND of literals). Basically, an SOP can be directly translated into a transistor-level network by transforming ANDs into serial connections and ORs into parallel connections and each literal is a transistor. To reduce the number of transistors, it is important to find common expressions that can be shared. At this point, a goal is to find a factorization that minimizes the number of literals.

To find a factored form there are mainly two methods: algebraic and Boolean. Algebraic methods are known to be fast but they cannot utilize some Boolean properties of the algebra. Boolean, instead, can exploit those opportunities at the cost of run time. Aspects of the technology implement both algebraic and Boolean algorithms have been implemented in the technology, referred to herein as sop factoring and transistor graph.

Transistor graph is a module that generates a single-stage transistor level network starting from a truth table. The algorithm takes a truth table, it generates an irredundant sum-of-products (ISOP) and factors it. The factored solution is represented as a AND-OR graph, where nodes can be ANDs or ORs and negations are allowed only for inputs and outputs. Factored forms are generated for both the target function and its complement. One will be assigned to the pullup network and one to the pulldown network. In one example, the algorithm for transistor graph works as follow:
1. The input is a target function f described by a truth table
2. The complement f′ is obtained by complementing the truth table
3. The ISOPs are generated from f and f′ using an implementation of the Minato-Morreale algorithm for truth tables
4. Both the ISOP for f and f′ are factored using weak (algebraic) or Boolean division
5. The functions are then assigned to the pulldown or the pullup network using a cost function based on the number of complemented variables cv to minimize the number of input and output inverters
   a. If cv(f)<cv(f)+1: f′ is assigned to the pulldown network and f(x₁′, x₂′, . . . , xₙ′) with complemented input variables to the pullup network
   b. If cv(f)<cv(f): f is assigned to the pulldown network and f(x₁′, x₂′, . . . , xₙ) with complemented input variables to the pullup network
6. The resulting ANDOR graph containing both implementations is returned

In one scenario, a Spice writer (or other analog electronic circuit simulator) can then take the generated ANDOR graph and dump it in a .spi file or equivalent file. Moreover, additional routines may be used to report statistics of the transistor level network and for validation.

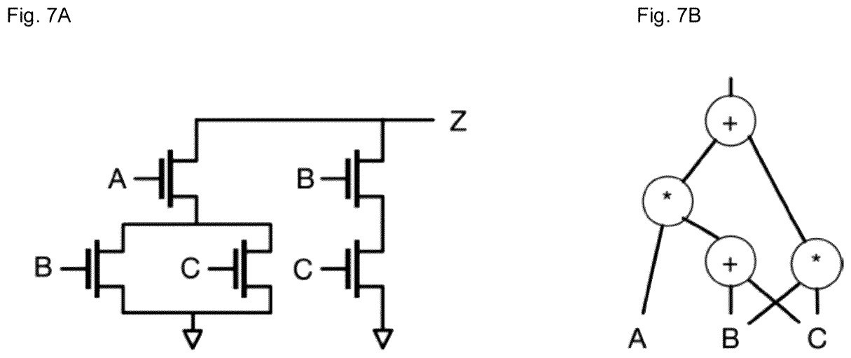

Another method can be used to generate all the transistor topologies that depend on how transistors in series are connected. The method creates one ANDOR graph for each one of the configurations. FIGS. 7A-B illustrate one example, in which FIG. 7A shows the circuit netlist/schematic and FIG. 7B shows a corresponding ANDOR graph. The number of topologies is 2\hat{ }(#ANDs in pulldown+#ANDs in pullup).

The following is an example command or other function to implement such features:

usage: transistor_network_generation [-bgwh] <-t func | -f func>

| | |
|---|---|
| | creates a transistor network for a given function. |
| -t <func> | read function as truth table in hex |
| -f <func> | read function as formula |
| -b | toggles use of Boolean factoring [default = yes] |
| -g | toggles writing the netlist for all the transistor |
| | configurations [default = no] |
| -w | writes the transistor netlist to file |
| -h | print the command usage |

Generating Multi-Stage Transistor Networks from Boolean Functions

The intuition behind a method used to scale the single-stage transistor network to multi-stage comes from noticing that realizing a multi-stage transistor network is equivalent to mapping a circuit into single-stage networks which are connected together. This problem is very well connected to logic synthesis. It involves logic synthesis and technology mapping.

The network is initially described as an AIG. According to one aspect, it is beneficial to optimize the network such that the result after mapping has fewer transistors as possible. The main concept here is to globally optimize for factored literals. It is important to realize that AIGs contain factored forms. Factored forms are composed by AND and OR nodes that have single fanout and no complementation. AIGs contain factored forms for all the logic cones that do not have multiple fanouts. If an additional fanout is present, that node must be considered as a new literal. Complementations can be partially ignored since they can be redistributed to literals nodes by the use of DeMorgan's law. Given an AIG, once can measure the number of factored form (FF) literals of the structure by: adding the internal fanout count of all the PIs (which are literals), adding the internal fanout count of all the nodes that have internal fanout count greater than one, and adding one for each remaining node (not counted before) that is a PO.

Factored form (FF) literals are well correlated with the number of gates in an AIG which is the most used cost function for logic synthesis nowadays. Nevertheless, to tackle this problem at the root, an optimization script can be used that optimizes specifically for FF literals. This involves: AIG rewriting for FF literals, AIG resubstitution for FF literals, refactoring, and technology mapping driven by FF literals. While addressed in detail in Appendix 1, these aspects are discussed below.

AIG rewriting is a DAG-aware optimization method that aims at minimizing the number of AND nodes by replacing small parts of the circuit using precomputed smaller structures. The advantage of being DAG-aware is to be able to reuse existing logic and to exploit structural hashing. AIG rewriting has been implemented to consider FF literals minimization as a new cost function rather than the size. To help to limit the network from increasing the number of AIG nodes and having a poor shape for other following optimization steps, size may be used as a second cost function, i.e., if literals cannot be improved, better size is accepted.

AIG resubstitution aims at minimizing the number of AND gates in an AIG by trying to replace some nodes by fewer ones starting from some divisors. The advantage of this method is to be able to exploit local don't cares during the optimization process. To speed up the algorithm, the divisors can be collected in a window around the node to replace. The method evaluates the resubstitution for one node at the time. The gain for a single node resub is evaluated by considering the number of nodes to remove if the resub is accepted, i.e., the nodes in the maximum fanout-free cone (MFFC). The new structure is built by combining the divisors until the right functionality is achieved and the number of gates generated is lower than the ones in the MFFC. The new version of the algorithm works similarly but considering the gain by counting the number of FF literals before and after the resub.

For refactoring, maximum fanout-free cones (MFFCs) are rewritten with a new factored implementation if the number of gates decreases.

Optimization flow, according to one scenario, utilizes a script where each command optimizes according to the literal cost. The script may include the following:
“rs -K 6; rw; rs -K 6 -N 2; rf; rs -K 8; rs -K 8 -N 2; rw; rs -K 10; rwz; rs -K 10 -N 2; rs -K 12; rfz; rs -K 12 -N 2; rwz; b”
   where:
rs is the AIG resubstitution for FF literals
rw is the AIG rewriting for FF literals
rwz is the AIG rewriting allowing zero again
rf is the refactoring algorithm
rfz is the refactoring allowing zero again
-K <num> specifies the maximum number of inputs of the window used for the local
optimization
-N <num> specifies the maximum number of new nodes inserted during resub

### Technology Mapping

A mapper, such as may be implemented at block 122 of FIG. 1, can be used to describe the circuit in terms of single stage gates. To achieve that, the mapper may use a precomputed library of gates (e.g., in the genlib format) that contains single-stage gates and their cost in terms of number of transistors. The internal mapper at block 122 may be extended with support for a generalized mapper, such as the “amap” mapper in the publicly available ABC verification tool.

### Netlist Generation

The following is an example approach for generating a Spice (or equivalent) netlist using a specified command. In one example, the command requires a library that is used to evaluate the functions' cost in terms of number of transistors. The command can be interfaced with ABC to perform the mapping.
usage: flex_map [-ICO <num>] [-bmcwdaspvruch]<lib_file><file> creates a transistor network for a given circuit.
-I<num> the max number of logic optimization iterations [default=100]
-C<num> the max number of cuts stored in tech mapping (0<num<250) [default=25]
-O the max number of logic optimization cycles [default=100]
-b toggle use of Boolean factoring in transistor-level synthesis [default=yes]
-m toggle call ABC for tech-mapping (ABC should be in PATH) [default=no]
-c toggle use structural choices for tech-mapping in ABC [default=no]
-w<file> write the transistor netlist to file
-d<file> write the verilog file of the used cells
-a<file> write the optimized AIG to file
-s<file> the name of the supergate library in the SUPER format
-p toggle printing spice file to user [default=no]
-v toggle printing optimization summary [default=no]
-r toggle printing optimization steps results [default=no]
-u report gates usage [default=no]
-c toggle comparison before the optimization [default=no]
-h print the command usage
lib_file the name of the library file to read in the GENLIB format
file the name of the file to read in the AIG or Verilog format,
   In which an example usage of the command is: flex_map -my -w res.spi 6_3_fin.spi design.v

### Enumerate Transistor Netlists

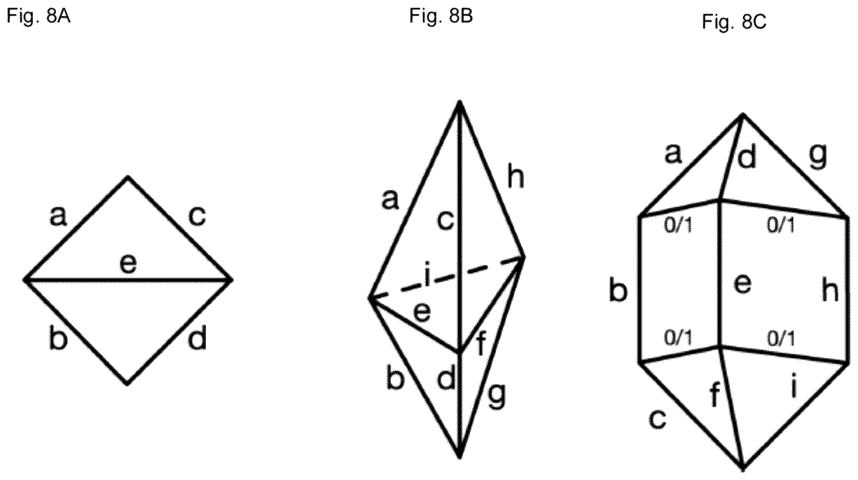

This aspect of the technology is used to enumerate various transistor networks given a few fixed topologies. Each segment in the topologies represents a transistor, each vertex is wire connecting two or more transistors. Example topologies are the ones shown in FIGS. 8A-C. In each example topology, the vertex on the top is considered as a connection to the output of the transistor network while the vertex in the bottom is considered as a connection to VSS. Basically, the topology is a pulldown network.

An algorithm to enumerate the transistor networks works as follows. Given a topology composed by m edges, assign each edge to a literal or a constant connection. A constant zero assignment represents a disconnected edge. A constant one assignment represents a wire connection with no transistors. Literals representing variables in the non-complemented and complemented polarity are used to find binate functions. Given n variables, 2+2*n literals are created. The enumeration problem involves assigning all the combinations of the literals to the m edges: (2+2*n)m combinations. For each combination, the functionality is extracted by simulating the network. Since the network is fixed, the function can be obtained in O(1) time using truth tables (represented on a 64-bit unsigned integer). In one example, the algorithm deals with up to 6 variables and 9 edges for a total of ˜2*10¹¹ combinations. This enumeration problem can be solved in a few minutes using existing computing resources.

For each combination, a cost based on the number of transistors is computed. That corresponds to the number of non-zero/one literals used in the topology. Each topology-function pair with the minimum cost is added to a hash map. At the end, the found functions and cost (and their corresponding dual) are written in a genlib library file. The cost associated with each gate in the library need not consider input and output inverters. However, the method may add inverter costs, filter and clean the library. Alternatively, the approach may only reduce the size of the library by including only the gates that are representative in their P-class (set of functions that are reachable by permuting the inputs).

An optimization can prune a considerable part of the search space by taking into account that one need not consider literals of negative polarity if the corresponding variable is not used in the positive polarity. This is because one can normalize the space to enumerate just one topology in a N-class (set of functions that are reachable by applying input negations). The other missing functions with the same topology can be found by enumerating input negations. Nevertheless, to construct a transistor library, it is not necessary to consider input negations. This trick translates into approximately a 10× speedup in compute time. The following is an example command:

```
usage: enumerate_transistor_netlists <vars> <stack> <library>
    enumerate transistor netlists.
  <vars> maximum number of variables
  <stack> maximum number of stacked transistors
  <library> output library name in the genlib format
```

### Auto-Creation of Custom Standard Cells

According to one aspect of the technology, the system is configured to analyze a set of design constraints and to extract a set of common functions. To achieve this task, a lookup table (LUT) mapper can be employed. The LUT mapper describes the logic in terms of connection of k-LUT, where k is the number of inputs. A k-LUT can implement any arbitrary function up to k inputs. Each LUT network is analyzed by the system to extract common functions that could be implemented at transistor level.

By way of example, an ad-hoc LUT mapper can use the factored form literals to estimate the number of transistors of a function. The LUT mapper can be cut-based. It may compute several k-feasible cuts for each node (single output logic cones with up to k inputs). Each one of them can be implemented as a k-LUT. The process runs a factorization process of the function and counts the number of literals as a proxy for transistors. Then the mapper uses a series of heuristics (such as area flow and exact area) to cover the network using the cuts while minimizing the total area.

In one scenario, a global remapping method is implemented based on factored form over AIGs. It performs cost-driven LUT mapping followed by Boolean decomposition of each LUT into an AIG. The algorithms in this scenario works by computing cuts for every node using a fast enumeration procedure, and assigning to each cut a cost based on the factored form decomposition. The factor form is computed starting from the ISOP extracted from the functionality of a cut. The SOP is then factored using factorization methods based on Algebraic or Boolean division. Mapping then selects the cuts such that the number of literals of the cuts covering the AIG is minimized.

According to one aspect, the system provides a GUI for a user such as an IC developer to input information about the system specification, architectural design, functional design and/or logic design, as shown in blocks 102-108 of FIG. 1. One or more processors of the system analyze these design constraints and extract a set of functions as described herein. The system can compare the information associated with those functions against the information in the standard cell library (e.g., library 124 of FIG. 1). The system determines which cells correspond to functions that are not in that library. In many instances, few functions may be very common, such as certain NAND, NOR, XOR and MUX arrangements. Uncommon functions, e.g., specific control or random logic functions, may not be found in the standard cell library.

This process can include searching for often occurring functions, which may be supported by the standard cell library. The system may analyze arithmetic, control and random logic. The system may extract functions that are not contained in the standard cell library. In one scenario, the system may describe the design using look-up tables (k-LUTs), which can realize any single output function of k inputs, as described herein. This may include mapping for area (minimizing the number of LUTs), classifying the extracted functions and counting how many times they appear, e.g., via NPN classification (such as input negation, input permutation, output negation).

The system may present information to the user regarding what kinds of cells are not in the standard cell library, and may automatically provide a recommendation for a custom standard cell to implement a particular function. The information to be presented may indicate the number of transistors, overall size, power requirements and/or other factors, etc. Upon receiving user input, the system may add such auto-generated custom standard cells to the standard cell library, or store them in a separate library. This approach provides enhanced flexibility and the ability to rapidly implement desired circuit functionality when features are not supported in an existing standard cell library.

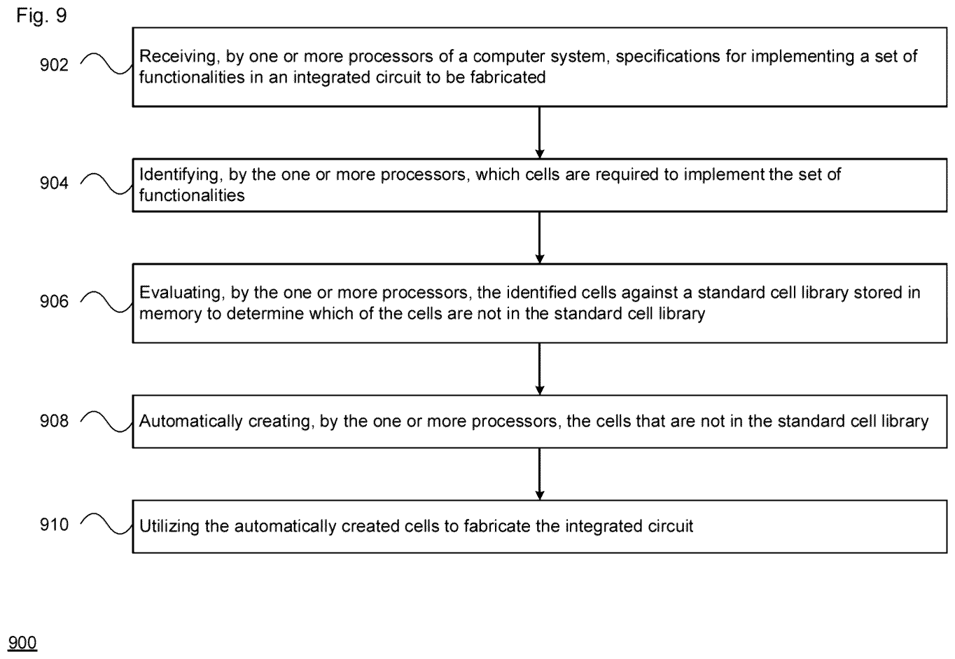

FIG. 9 illustrates an example method 900 in accordance with the above discussion. The method includes, at block 902, receiving, by one or more processors of a computer system, specifications for implementing a set of functionalities in an integrated circuit to be fabricated. Then at block 904 the method includes identifying, by the one or more processors, which cells are required to implement the set of functionalities. At block 906, the method includes evaluating, by the one or more processors, the identified cells against a standard cell library stored in memory to determine which of the cells are not in the standard cell library. Next, at block 908 the method includes automatically creating, by the one or more processors, the cells that are not in the standard cell library. And at block 910, the method includes utilizing the automatically created cells to fabricate the integrated circuit.

Although the technology herein has been described with reference to particular embodiments and configurations, it is to be understood that these embodiments and configurations are merely illustrative of the principles and applications of the present technology. It is therefore to be understood that numerous modifications may be made to the illustrative embodiments and configurations, and that other arrangements may be devised without departing from the spirit and scope of the present technology as defined by the appended claims.

1. A computer-implemented method, comprising:
receiving, by one or more processors of a computer system, specifications for implementing a set of functionalities in an integrated circuit to be fabricated;
identifying, by the one or more processors, which cells are required to implement the set of functionalities;
evaluating, by the one or more processors, the identified cells against a standard cell library stored in memory to determine which of the cells are not in the standard cell library;
automatically creating, by the one or more processors, the cells that are not in the standard cell library; and
utilizing the automatically created cells to fabricate the integrated circuit.

2. The method of claim 1, further comprising storing the automatically created cells in the memory.

3. The method of claim 2, wherein storing the automatically created cells in the memory includes adding the automatically created cells to the standard cell library.

4. The method of claim 1, further comprising:
generating, by the one or more processors for presentation via a graphical user interface, a recommendation to a user regarding employing the automatically created cells to fabricate the integrated circuit.

5. The method of claim 4, wherein the recommendation includes information of at least one of a number of transistors utilized, overall cell size, or a power requirement.

6. The method of claim 1, wherein evaluating the identified cells against the standard cell library includes employing a lookup table (LUT) mapper.

7. The method of claim 6, further comprising the LUT mapper using factored form literals to estimate a number of transistors of a function to be utilized by the integrated circuit.

8. The method of claim 6, wherein the LUT mapper is cut-based.

9. The method of claim 8, further comprising the LUT mapper using a series of heuristics to cover a network using cuts while minimizing total area.

10. The method of claim 7, further comprising performing global remapping based on the factored form literals over an And-inverter graph (AIG).

11. A computing system, comprising:
memory configured to store a standard cell library; and
one or more processors operatively coupled to the memory, the one or more processors being configured to:
receive specifications for implementing a set of functionalities in an integrated circuit to be fabricated;
identify which cells are required to implement the set of functionalities;
evaluate the identified cells against the standard cell library stored in the memory to determine which of the cells are not in the standard cell library;
automatically create the cells that are not in the standard cell library; and
cause fabrication of the integrated circuit utilizing the automatically created cells.

12. The computing system of claim 11, wherein the one or more processors are further configured to store the automatically created cells in the memory.

13. The computing system of claim 12, wherein storing the automatically created cells in the memory includes causing the automatically created cells to be added to the standard cell library.

14. The computing system of claim 11, wherein the one or more processors are further configured to generate, for presentation via a graphical user interface, a recommendation to a user regarding employing the automatically created cells to fabricate the integrated circuit.

15. The computing system of claim 14, wherein the recommendation includes information of at least one of a number of transistors utilized, overall cell size, or a power requirement.

16. The computing system of claim 11, wherein evaluation of the identified cells against the standard cell library includes employing a lookup table (LUT) mapper.

17. The computing system of claim 16, wherein the one or more processors are further configured to apply the LUT mapper using factored form literals to estimate a number of transistors of a function to be utilized by the integrated circuit.

18. The computing system of claim 16, wherein the LUT mapper uses a series of heuristics to cover a network using cuts while minimizing total area.

19. The computing system of claim 17, wherein the one or more processors are further configured to perform global remapping based on the factored form literals over an And-inverter graph (AIG).

20. The computing system of claim 11, wherein the one or more processors are configured to cause fabrication of the integrated circuit utilizing the automatically created cells by transmitting a file containing the automatically created cells to a fabrication facility.
